(19) United States
(12) Patent Application Publication
(10) Pub. No.: US 2025/0079394 A1
(43) Pub. Date: Mar. 6, 2025

(54) Compensating for registration error in vertical die stacking

(71) Applicant: Marvell Asia Pte Ltd, Singapore (SG)

(72) Inventors: Runzi Chang, Saratoga, CA (US); Lijuan Zhang, Fremont, CA (US); Jie Chen, Taipei City (TW)

(21) Appl. No.: 18/789,823

(22) Filed: Jul. 31, 2024

Related U.S. Application Data
(60) Provisional application No. 63/536,251, filed on Sep. 1, 2023.

(51) Int. Cl. H01L 23/00

(52) U.S. Cl. CPC H01L 24/80; H01L 24/74; H01L 2224/74; H01L 2224/80132

(57) ABSTRACT

A method for fabricating an electronic device having two or more stacked integrated circuit (IC) dies, the method includes, disposing a first IC die on a substrate. A registration error of the first IC die between (i) a first intended position of the first IC die on the substrate, and (ii) a first actual position of the first IC die on the substrate, is determined. A second IC die is stacked on the first IC die, and at least part of the registration error of the first IC die is compensated for by shifting the second IC die, from a second intended position to a second actual position.

### CROSS-REFERENCE TO RELATED APPLICATIONS

This application claims the t benefit of U.S. Provisional Patent Application 63/536,251, filed Sep. 1, 2023, whose disclosure is incorporated herein by reference.

### FIELD OF THE DISCLOSURE

The present invention relates generally to packaging of electronic devices, and particularly to methods and systems for improving alignment between integrated circuit (IC) dies stacked vertically in a package of an electronic device.

### BACKGROUND

Various techniques for stacking and packaging two or more IC dies on one another are known in the art. Electrical connections between the stacked IC dies are typically carried out using through-silicon vias (TSV) fabricated in some or all of the IC dies (and/or in interposers vertically connecting between IC dies), and pads for electrically connecting between the TSVs or between TSVs of a first IC die, and other electrically conductive traces formed in a second IC die stacked over the first IC die. In such structures, misalignment between the electrical connections of adjacently stacked IC dies, may result in malfunctioning of electronic devices comprising vertically stacked IC dies.

The description above is presented as a general overview of related art in this field and should not be construed as an admission that any of the information it contains constitutes prior art against the present patent application.

### SUMMARY

An embodiment of the present invention that is described herein provides a method for fabricating an electronic device having two or more stacked integrated circuit (IC) dies. The method includes, disposing a first IC die on a substrate. A registration error of the first IC die between (i) a first intended position of the first IC die on the substrate, and (ii) a first actual position of the first IC die on the substrate, is determined. A second IC die is stacked on the first IC die, and at least part of the registration error of the first IC die is compensated for by shifting the second IC die, from a second intended position to a second actual position.

In some embodiments, stacking the second IC die includes (i) disposing the second IC die on an additional substrate at the second actual position, (ii) positioning the additional substrate facing the substrate, and (iii) stacking the second IC die on the first IC die by stacking the additional substrate on the substrate. In other embodiments, the method includes determining an additional registration error between (i) the second actual position, and (ii) a specified second position of the second IC die, and shifting the second IC die includes compensating for (a) the registration error and (b) the additional registration error. In yet other embodiments, determining the registration error and the additional registration error includes: (i) holding the first and second intended positions, (ii) measuring the first and second actual positions, and (iii) determining the registration error and the additional registration error based on the first and second intended positions and the first and second actual positions.

In some embodiments, the method includes determining an overlay error between the first actual position and the second actual position, and shifting the second IC die includes compensating for (a) the registration error, and (b) the overlay error. In other embodiments, the method includes adjusting the second actual position of the second IC die based on the overlay error. In yet other embodiments, the method includes disposing (i) one or more additional first IC dies on the substrate, (ii) one or more additional second IC dies on the additional substrate, (iii) a first filling material on a first surface of the substrate, the first filling material positioned at least between the first IC die and the one or more additional first IC dies, and (iv) a second filling material on a second surface of the additional substrate, the second filling material being positioned at least between the second IC die and the one or more additional second IC dies.

In some embodiments, the method includes bonding between at least the first IC die and the second IC die. In other embodiments, the substrate includes registration marks, and determining the registration error includes (i) holding the first intended position of the first IC die relative to the registration marks, and (ii) receiving a signal indicative of the first actual position of the first IC die relative to the registration marks. In yet other embodiments, the first and second IC dies including (i) first and second active sides, respectively that have ICs, and (ii) first and second passive sides, opposite the first and second active sides, respectively, disposing the first IC die includes disposing the first active side on the substrate, and stacking the second IC die includes stacking the second active side of the second IC die on the first passive side of the first IC die.

There is additionally provided, in accordance with an embodiment of the present invention, an apparatus for fabricating an electronic device having two or more stacked integrated circuit (IC) dies, the apparatus including a substrate, and first and second IC dies. The substrate has registrations marks. The first IC die is disposed on the substrate at a first actual position, and a registration error of the first IC die between (i) a first intended position of the first IC die on the substrate, and (ii) the first actual position of the first IC die, is determined based on at least one of the registration marks. The second IC die is stacked on the first IC die, the second IC die is shifted from a second intended position to a second actual position to compensate for at least part of the registration error.

The present disclosure will be more fully understood from the following detailed description of the embodiments thereof, taken together with the drawings in which:

### BRIEF DESCRIPTION OF THE DRAWINGS

FIG. 1 is a schematic, sectional view of process operations for fabricating an electronic device by stacking a first set of multiple IC dies over a second set of multiple IC dies, respectively, in accordance with an embodiment that is described herein;

FIG. 2 is a schematic, sectional view of other process operations for fabricating the electronic device of FIG. 1 by stacking the first set of multiple IC dies over the second set of multiple IC dies, respectively, in accordance with an alternative embodiment that is described herein; and

FIG. 3 is a flow chart that schematically illustrates a method for fabricating the electronic device of FIGS. 1 and 2, in accordance with an embodiment that is described herein.

### DETAILED DESCRIPTION OF EMBODIMENTS

Embodiments of the present disclosure that are described herein provide techniques for improving alignment between IC dies stacked vertically in a package of an electronic device.

In some embodiments, IC dies that are to be fabricated on a substrate (e.g., a silicon wafer), are sorted to good IC dies that pass all tests and are fully functional, and to bad IC dies that failed the tests and are intended to be scrapped. Subsequently, the substrate is thinned (e.g., using a back grinding process for reducing the thickness of the IC dies), and the IC dies are separated from one another using a dicing process. After separating the IC dies, a pick and place (PP) system picks the known good IC dies (KGDs) and places each KGD at an intended position, in the present example, on a carrier substrate, for example, another wafer typically made from silicon, or alternatively from glass (in some applications). It is noted that alignment between the electrical connections of adjacently stacked IC dies of an electronic device is crucial for achieving desired functionality and high quality (e.g., operational frequency and/or failure resilience at high temperatures) of the electronic device.

In some embodiments, a method for improving the alignment between stacked IC dies of the electronic device, comprises: (i) disposing one or more first IC dies on a carrier substrate, (ii) measuring, for each of the first IC dies, a registration error between the intended position and the actual position of the respective first IC die, and (iii) stacking one or more second IC dies on the one or more first IC dies, respectively, and compensating for the registration error in each of the first IC dies, by shifting each of the respective second IC dies, from the intended second die position to an actual second IC die position based on the actual position of the first IC dies.

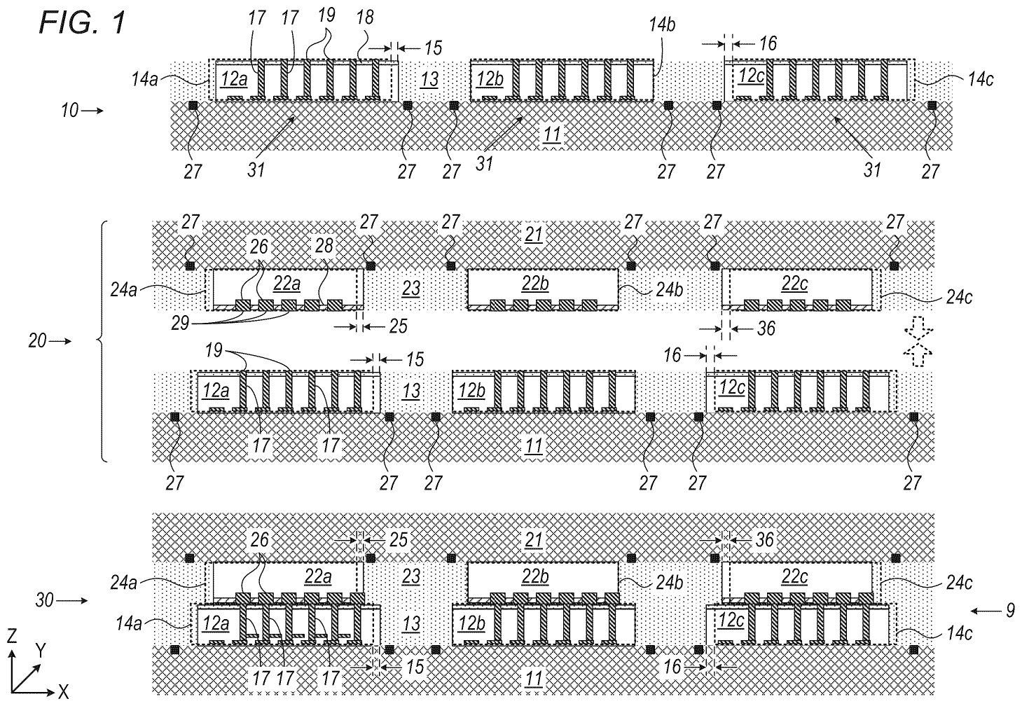

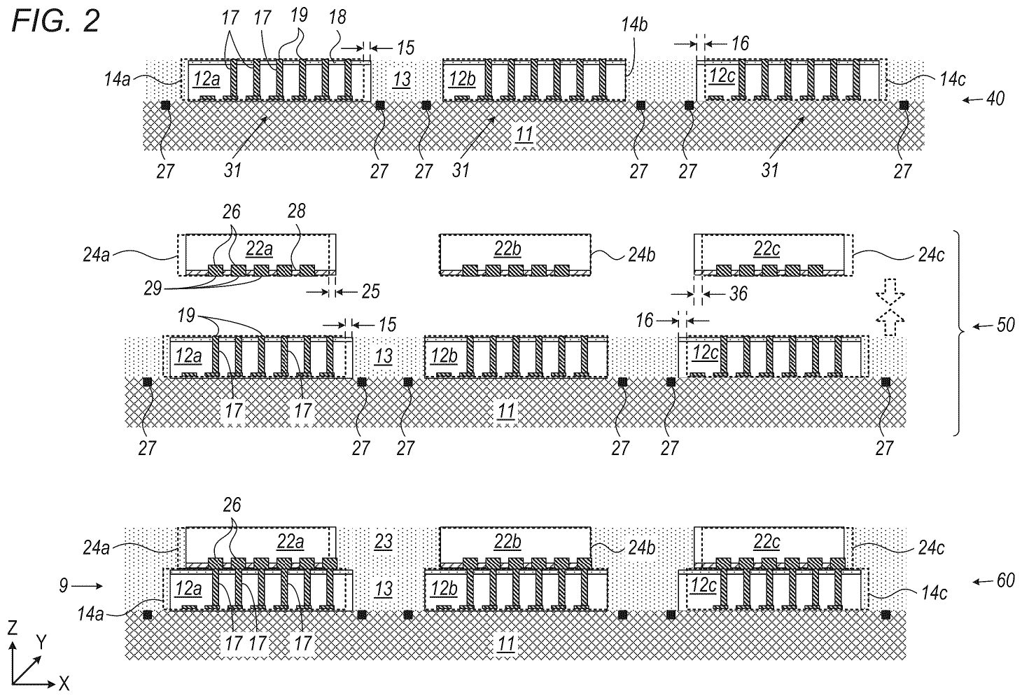

In some embodiments, in a first technique, each second IC die may be disposed with the respective shift on an additional substrate (e.g., an additional carrier), and the first and second IC dies are stacked by facing them toward one another and coupling between the substrate and the additional substrate. In a second alternative technique, each second IC die is directly disposed, with the respective shift, on the respective first IC die. Both techniques are described in detail in FIGS. 1 and 2 below.

The description above is presented as a general overview of embodiments of the present disclosure, which are described in detail herein.

FIG. 1 is a schematic, sectional view of process operations 10, 20 and 30, for fabricating an electronic device 9 (shown in operation 30) by stacking a first set of multiple IC dies 22a, 22b and 22c over a second set of multiple IC dies 12a, 12b and 12c, respectively, in accordance with an embodiment that is described herein.

In some embodiments, IC dies 12 were fabricated on a silicon substrate (not shown) and tested to determine known good dies (KGDs) such as IC dies 12a, 12b and 12c, and to scrap known bad dies (not shown). Subsequently, the silicon substrate was thinned using a back grinding process, and then separated from one another using a dicing process.

Reference is now made to operation 10. In some embodiments, each of IC dies 12a, 12b and 12c has an active side having one or more active areas 31, and a passive side opposite the active side. Moreover, each of IC dies 12a, 12b and 12c has electrical connections, such as through silicon vias (TSVs) 17, configured to conduct electrical signals between active areas 31 of the respective IC die 12 and an additional IC die (shown in operations 20 and 30 below) stacked over or under the respective IC die 12, as will be described in more detail in operations 20 and 30 below.

In the example of operation 10, IC dies 12a, 12b and 12c are flipped and their active areas 31 are mounted over a carrier substrate 11 using a pick and place (PP) system (not shown). It is noted that each of the KGDs (e.g., IC dies 12a-12c) has an intended position on the surface of substrate 11. In the present example, IC die 12a has an intended position 14a, IC die 12b has an intended position 14b, and IC die 12c has an intended position 14c. Respective intended positions are depicted using phantom lines. After mounting IC dies 12a-12c, a filling material 13 is disposed on the outer surface of substrate 11 so as to fill the gaps between IC dies 12, and to protect the outer surface of IC dies 22a-22c. Filling material 13 is further configured to fix in place IC dies 12a, 12b and 12c at their actual positions. Moreover, a dielectric layer 18 is formed over the outer surface of IC dies 12, and subsequently, filling material 13 is patterned to expose outer surfaces 19 of TSVs 17 for conducting the electrical signals between the IC dies of the stack, as will be shown in operation 30 below.

In some cases, variations in the operation of the PP system may result in a registration error between the intended position and the actual position of one or more of IC dies 12. The registration error may occur along at least one of X-axis and Y-axis. In the example of operation 10, (i) a registration error 15 occurred between the intended position 14a and the actual position of IC die 12a, (ii) IC die 12b placed without a registration error so that the actual position is similar to the intended position 14b, and (iii) a registration error 16 occurred between the intended position 14c and the actual position of IC die 12c. It is noted that registration errors 15 and 16 typically differ from one another because the PP system places each IC die 12 in a separate pick and place process.

In some embodiments, after disposing IC dies 12a-12c on substrate 11, a registration measurement is carried out in operation 10. In the present example, substrate 11 has registration marks 27, and based on at least one of registration marks 27, the registration measurement system (not shown) is configured to (i) measure the actual position of IC dies 12 with respect to the positions of marks 27, and (ii) generate a signal indicative of the measured actual position of IC dies 12. In some embodiments, based on intended position 14 and the measured actual position of each IC die 12, a processor of the registration measurement system is configured to determine the registration error between the intended position 14 and the actual position of each IC die 12. In the present example, registration error 15 between the intended position 14a and the actual position of IC die 12a, and registration error 16 between the intended position 14c and the actual position of IC die 12c.

Reference is now made to operation 20. In some embodiments, the processor of the PP system is configured to control the PP system to dispose IC dies 22a, 22b and 22c on the surface of an additional carrier substrate, referred to herein as a substrate 21. It is noted that substrate 21 and IC dies 22a, 22b and 22c are flipped, so that IC dies 22a, 22b and 22c are facing IC dies 12a, 12b and 12c disposed on substrate 11. Moreover, IC dies 22a, 22b and 22c have intended positions 24a, 24b and 24c, respectively, and the actual placement positions of IC dies 22a-22c on substrate 21 are described in detail below.

In the example configuration of electronic device 9, IC dies 22a, 22b and 22c are intended to be stacked on IC dies 12a, 12b and 12c, respectively. The stacking is carried out by facing IC dies 12 and 22 one against the other and moving substrates 11 and 21 toward one another for performing the stacking of the IC dies, as will be shown in operation 30 below. In the present example, IC dies 22a-22c have a dielectric layer 28, which is patterned to fabricate electrically conductive pads 26 having outer surfaces 29, which are exposed at the outer surface of IC dies 22a-22c and are intended to be bonded to respective surfaces 19 of TSVs 17. Pads 26 and TSVs 17 are typically made from copper, but may comprise any other suitable metal, such as but not limited to aluminum, an alloy of aluminum and copper, titanium and tungsten. Dielectric layer 28 may be similar to dielectric layer 18 of IC dies 12a-12c, and may be based on silicon dioxide, or may have a different composition that than of dielectric layer 18. In the context of the present disclosure and in the claims, the electrically conductive pads 26 are formed in an active side of each of IC dies 22a-22c, and a passive side of IC dies 22a-22c is facing the active side of IC dies 22a-22c.

It is noted that the diameter of TSVs 17 in the XY plane is typically smaller than that of pads 26. As such, registration errors in the placement of at least one of IC dies 12 and 22, may cause a reduced overlap between surfaces 19 and 29. The reduced overlap may result in an increased electrical resistance in conducting of electrical signals between one or more pairs of TSV 17 and pad 26.

In some cases, electrical traces, such as additional pads (not shown) may be formed on surface 19 for increasing the lateral area connecting between TSVs 17 and pads 26. Such electrical traces, however, are formed using lithography processes, and may not be able to compensate for the registration errors in the placement of IC dies 12 and 22 on substrates 11 and 21, respectively.

In some embodiments, in the placement of IC dies 22a-22c on substrate 21, the processor of the PP system is configured to compensate for at least some registration errors 15 and 16 determined in operation 10. In the present example, the processor of the PP system is configured to (i) shift the placement of IC die 22a along the X-axis and/or Y-axis, from the intended position 24a by a distance 25 to compensate for registration error 15, and (ii) shift the placement of IC die 22c along the X-axis and/or Y-axis, from the intended position 24c by a distance 36 to compensate for registration error 16. As described in operation 10 above, IC die 12b was placed at its intended position 14b (without registration error. As such, no compensation is required, and the processor of the PP system is configured to control the robotic arm of the PP system to place IC die 22b at its intended position 24b.

In some embodiments, after placing IC dies 22a-22c, substrate 21 may be inserted into the registration measurement system, so as to determine whether the actual positions of IC dies 22a and 22c compensate for the registration errors 15 and 16. Moreover, the registration measurement verifies that no registration error occurred between the intended position 24b, and the actual position of IC die 22b. In case of a discrepancy, operation 20 may be (i) corrected by adjusting the position of one or more of IC dies 22 on substrate 21, or (ii) reworking operation 20 by placing another set of IC dies 22 on another substrate 21, and measuring the registration error to determine whether the actual positions of IC dies 22a and 22c compensate for the registration errors 15 and 16.

In some embodiments, after confirming the correct positioning of IC dies 22a-22c on substrate 21, a filling material 23 is applied to the outer surface of substrate 21 so as to fill the gaps between IC dies 22, and to protect the outer surface of IC dies 22a-22c. Filling material 23 is further configured to fixate IC dies 22a, 22b and 22c at their actual positions.

In some embodiments, in response to (i) compensating for registration errors 15 and 16, and (ii) confirming the correct placement of IC dies 22a-22c, substrates 11 and 21 are being moved relative to one another for stacking IC dies 22a, 22b and 22c, on IC dies 12a, 12b and 12c, respectively.

Reference is now made to operation 30. In some embodiments, after stacking IC dies 22a, 22b and 22c, on IC dies 12a, 12b and 12c, respectively, a bonding process is carried out for (i) bonding between dielectric layers 18 and 28, and (ii) bonding between surfaces 19 of TSVs 17, and surfaces 29 of pads 26. The hybrid bonding process may comprise preparation of surfaces 19 and 29, followed by a thermal annealing process for bonding between respective surfaces 19 and 29. Moreover, after concluding the bonding, substrates 11 and 21 may be removed and electronic device 9 may be integrated in any suitable type of electronic system (not shown).

In some embodiments, surfaces 19 and 29 are directly bonded to one another, i.e., without any bonding materials disposed therebetween, as shown in the sectional view of operation 30. It is noted that (i) by confirming in operation 20 that shifting in distances 25 and 36 compensate for registration errors 15 and 16, no additional electrical traces and/or pads are required, and (ii) by applying the hybrid bonding process, no bonding material is required between surfaces 19 and 29. As such, the disclosed techniques reduce the number of process operations, and reduce the costs associated with the fabrication of electronic device 9.

FIG. 2 is a schematic, sectional view of process operations 40, 50 and 60 for fabricating electronic device 9 (shown in operation 60) by stacking IC dies 22a-22c directly over IC dies 12a-12c, respectively, in accordance with another embodiment that is described herein.

In some embodiments, the fabrication process begins at operation 40, which is similar to operation 10 of FIG. 1 above. Reference is now made to operation 50. In some embodiments, IC dies 22a, 22b and 22c are placed by the PP system directly on IC dies 12a, 12b, and 12c, respectively. In such embodiments, the shifts in distances 25 and 36 are typically similar to that in operation 20 of FIG. 1 above, but filling material 23 is not disposed in operation 50. Moreover, after placing IC dies 22a, 22b and 22c over IC dies 12a, 12b, and 12c, respectively, an overlay measurement is carried out by an overlay system in order to measure an overlay error between the positions of each pair of IC dies 12 and 22. In the present example, IC dies 22a, 22b and 22c are intended to be placed over IC dies 12a, 12b, and 12c, respectively. As such, the term overlay error refers to any relative displacement, from the intended position, of a given IC die 12 (e.g., IC die 12a) in relation to a respective IC die 22 (e.g., IC die 22a). For example, the overlay measurement is carried out after placing IC die 22c over IC die 12c, to confirm correct placement of IC die 22c. In such embodiments, the overlay measurement is carried out instead of the second registration measurement described in operation 20 above. Moreover, in case the overlay error exceeds a predefined threshold, the processor is configured to (i) control the PP system to pick IC die 22c, and rework the placement of IC die 22c on IC die 12c in order to have the overlay error smaller than the predefined threshold, and subsequently, (ii) control the overlay system to remeasure the overlay error after the replacement of IC die 22c on IC die 12c. In other words, in case the overlay error exceeds a predefined threshold, the processor is configured to adjust the position of at least one of IC dies 22a-22c.

Reference is now made to operation 60. In some embodiments, filling material 23 may be disposed over filling material 13, and subsequently, the bonding process is carried out using the techniques described in operation 30 of FIG. 1 above. In other embodiments, the bonding process is carried out before disposing filling material 23.

In alternative embodiments, filling materials 13 and 23 may be disposed in a single process operation, after performing the stacking and bonding processes in operations 50 and 60. This sequence of process operations (i) reduces the number of processes (by applying the filling materials 13 and 23 in a single process step), and (ii) keeps the visibility of registration marks 27 (by the optical-based registration system) after stacking IC dies 22 of IC dies 12, and thereby, allows performance of a registration measurement between the intended position 24 and the actual placement position of each IC die 22.

In some embodiments, the techniques described in FIGS. 1 and 2 above improve the alignment between TSVs 17 and pads 26 to reduce the resistance in the interface between IC dies 12 and 22. Moreover, the techniques described in FIGS. 1 and 2 above enable directly connecting TSVs 17 and pads 26, without any sort of electrical traces, pads and bonding materials formed between surfaces 19 and 29 of TSVs 17 and pads 26, respectively. It is noted that the techniques described above are applicable, with necessary changes, to improve the alignment and direct connection between any electrical connections (other than TSVs and/or pads) in stacked IC dies, such as IC dies 12 and 22.

This particular configuration of electronic device 9 is shown by way of example, in order to illustrate certain problems that are addressed by embodiments of the present invention and to demonstrate the application of these embodiments in enhancing the performance of such an electronic device. Embodiments of the present invention, however, are by no means limited to this specific sort of example electronic device, and the principles described herein may similarly be applied to other configurations of electronic devices. For example, in alternative embodiments, IC dies 12a, 12b and 12b may be flipped with the passive side having dielectric layer 18 being disposed on carrier substrate 11 and active area 31 facing conductive pads 26. This configuration is referred to herein as face-to-face in which the active areas of each pair of IC dies 12 and 22 are facing one another. As such, the configuration shown in FIGS. 1 and 2 is also referred to herein as face-to-back in which the active area of one IC die (e.g., IC die 22) is stacked on a passive area of the other IC die (e.g., IC die 12). In yet other embodiments, at least one pair of IC dies 12 and 22 may be arranged in a back-to-back configuration in which the passive side of IC dies 12 and 22 (i.e., the side opposite active areas 31 in IC die 12, and the side opposite conductive pads 26 in IC die 22) are stacked and bonded to one another.

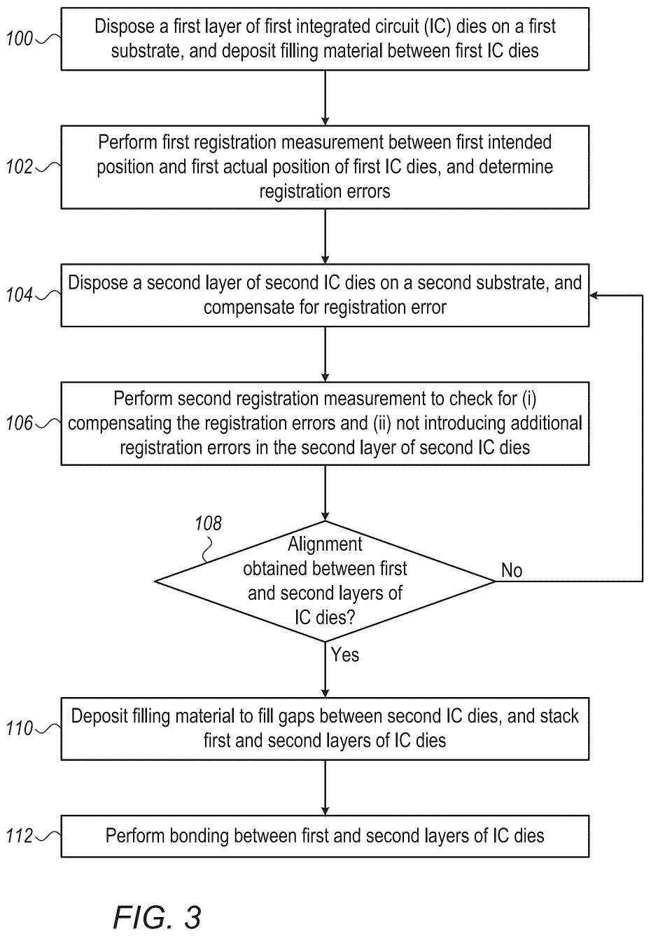

FIG. 3 is a flow chart that schematically illustrates a method for fabricating electronic device 9 shown in FIGS. 1 and 2 above, in accordance with an embodiment that is described herein. It is noted that the flow chart described herein is based on the process flow of FIG. 1 above. As will be described below, the flow chart is also applicable for fabricating electronic device 9 using the alternative technique shown in FIG. 2 above.

The method begins with a first die placement operation 100, with disposing IC dies 12a-12c on substrate 11 and depositing filling material to fill gaps between pairs of IC dies 12, as described in detail in FIG. 1 above.

At a first registration determination operation 102, substrate 11 with IC dies 12a-12c is inserted into a registration measurement system to perform registration measurements, and to determine registration errors 15 and 16 between the intended position and the actual position of each IC die among IC dies 12a, 12b and 12c, as described in detail in FIG. 1 above.

At a second die placement operation 104, IC dies 22a, 22b and 22c, are placed on substrate 21 with compensation for at least part of the registration errors 15 and 16 (determined in operation 102 above) by shifting IC dies 22a and 22c from their respective intended positions 24a and 24c to their actual positions on substrate 21, as shown and described in detail in FIG. 1 above.

At a second registration determination operation 106, substrate 21 with IC dies 22a-22c is inserted into the registration measurement system to perform registration measurements, and to check whether the compensation for at least part of the registration errors 15 and 16, is obtained.

At a decision operation 108, the processor checks that alignment has been obtained between the actual positions of the first and second layers of IC dies. In case the compensation failed and/or insufficient level of alignment was obtained, the method loops back to operation 104 and the processor controls the PP system to pick at least one of IC dies 22a, 22b and 22c, and to rework the placing of the respective IC die 22 to perform the compensation.

Alternatively, in case the required level of alignment between the pairs of IC dies 12 and 22, is obtained, the method proceeds to a die stacking operation 110, with moving substrates 11 and 21 toward one another, and stacking IC dies 22a, 22b and 22c over IC dies 12a, 12b and 12c, respectively, as described in detail in FIG. 1 above.

At a bonding operation 112 that concludes the method, IC dies 22a, 22b and 22c are bonded with IC dies 12a, 12b and 12c, respectively, as described in detail in FIG. 1 above.

In other embodiments, in operation 104 IC dies 22a, 22b, and 22c are placed directly on IC dies 12a, 12b, and 12c, respectively, and an overlay measurement is performed in operation 106 (instead of performing the second registration measurement), as described in detail in FIG. 2 above.

It is noted that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. A method for fabricating an electronic device having two or more stacked integrated circuit (IC) dies, the method comprising:
disposing a first IC die on a substrate;
determining a registration error of the first IC die between (i) a first intended position of the first IC die on the substrate, and (ii) a first actual position of the first IC die on the substrate; and
stacking a second IC die on the first IC die, and compensating for at least part of the registration error of the first IC die by shifting the second IC die, from a second intended position to a second actual position.

2. The method according to claim 1, wherein stacking the second IC die comprises (i) disposing the second IC die on an additional substrate at the second actual position, (ii) positioning the additional substrate facing the substrate, and (iii) stacking the second IC die on the first IC die by stacking the additional substrate on the substrate.

3. The method according to claim 2, further comprising determining an additional registration error between (i) the second actual position, and (ii) a specified second position of the second IC die, and wherein shifting the second IC die comprises compensating for (a) the registration error and (b) the additional registration error.

4. The method according to claim 3, wherein determining the registration error and the additional registration error comprises: (i) holding the first and second intended positions, (ii) measuring the first and second actual positions, and (iii) determining the registration error and the additional registration error based on the first and second intended positions and the first and second actual positions.

5. The method according to claim 1, further comprising determining an overlay error between the first actual position and the second actual position, and wherein shifting the second IC die comprises compensating for (a) the registration error, and (b) the overlay error.

6. The method according to claim 5, further comprising adjusting the second actual position of the second IC die based on the overlay error.

7. The method according to claim 1, and comprising disposing (i) one or more additional first IC dies on the substrate, (ii) one or more additional second IC dies on the additional substrate, (iii) a first filling material on a first surface of the substrate, the first filling material positioned at least between the first IC die and the one or more additional first IC dies, and (iv) a second filling material on a second surface of the additional substrate, the second filling material being positioned at least between the second IC die and the one or more additional second IC dies.

8. The method according to claim 1, further comprising bonding between at least the first IC die and the second IC die.

9. The method according to claim 1, wherein the substrate comprises registration marks, and wherein determining the registration error comprises (i) holding the first intended position of the first IC die relative to the registration marks, and (ii) receiving a signal indicative of the first actual position of the first IC die relative to the registration marks.

10. The method according to claim 1, wherein the first and second IC dies comprising (i) first and second active sides, respectively that have ICs, and (ii) first and second passive sides, opposite the first and second active sides, respectively, wherein disposing the first IC die comprises disposing the first active side on the substrate, and stacking the second IC die comprises stacking the second active side of the second IC die on the first passive side of the first IC die.

11. An apparatus for fabricating an electronic device having two or more stacked integrated circuit (IC) dies, the apparatus comprising:
a substrate having registrations marks;
a first IC die disposed on the substrate at a first actual position, wherein a registration error of the first IC die between (i) a first intended position of the first IC die on the substrate, and (ii) the first actual position of the first IC die, is determined based on at least one of the registration marks; and
a second IC die stacked on the first IC die, the second IC die is shifted from a second intended position to a second actual position to compensate for at least part of the registration error.

12. The apparatus according to claim 11, wherein the second IC die is disposed on an additional substrate at the second actual position, the additional substrate is positioned to face the substrate, and the second IC die is stacked on the first IC die by stacking the additional substrate on the substrate.

13. The apparatus according to claim 12, wherein the additional substrate comprises additional registration marks, wherein an additional registration error between (i) the second actual position, and (ii) a specified second position of the second IC die, is determined based on at least one of the additional registration marks, and wherein the second IC die is shifted to compensate for (a) the registration error and (b) the additional registration error.

14. The apparatus according to claim 13, wherein the determination of the registration error and the additional registration error comprises: (i) holding the first and second intended positions, (ii) measurements of the first and second actual positions, and (iii) determination of the registration error and the additional registration error based on the first and second intended positions and the first and second actual positions.

15. The apparatus according to claim 11, wherein an overlay error is determined between the first actual position and the second actual position, and wherein the second IC die is shifted to compensate for (a) the registration error, and (b) the overlay error.

16. The apparatus according to claim 15, wherein the second actual position of the second IC die is adjusted based on the overlay error.

17. The apparatus according to claim 11, wherein (i) one or more additional first IC dies are disposed on the substrate, (ii) one or more additional second IC dies are disposed on the additional substrate, (iii) a first filling material is disposed on a first surface of the substrate, the first filling material being positioned at least between the first IC die and the one or more additional first IC dies, and (iv) a second filling material is disposed on a second surface of the additional substrate, the second filling material being positioned at least between the second IC die and the one or more additional second IC dies.

18. The apparatus according to claim 11, wherein at least the first IC die and the second IC die are bonded.

19. The apparatus according to claim 11, wherein the registration error is determined by: (i) the first intended position of the first IC die relative to the at least one of the registration marks, and (ii) a signal indicative of the first actual position of the first IC die relative to the at least one of the registration marks.

20. The apparatus according to claim 11, wherein the first and second IC dies comprising (i) first and second active sides, respectively that have ICs, and (ii) first and second passive sides opposite the first and second active sides, respectively, wherein the first active side of the first IC die is disposed on the substrate, and the second active side of the second IC die is disposed on the first passive side of the first IC die.
